(19) United States
(12) Patent Application Publication
(10) Pub. No.: US 2008/0284017 A1
(43) Pub. Date: Nov. 20, 2008

(54) METHODS OF FABRICATING CIRCUIT BOARD AND SEMICONDUCTOR PACKAGE, AND CIRCUIT BOARD AND SEMICONDUCTOR PACKAGE FABRICATED USING THE METHODS

(75) Inventors: Teak-Hoon LEE, Gyeonggi-do (KR); Eun-Chul AHN, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/112,998

(22) Filed: Apr. 30, 2008

(30) Foreign Application Priority Data
May 17, 2007 (KR) 2007-0048291

(51) Int. Cl. H01L 23/488; H05K 1/03

(52) U.S. Cl. 257/738; 174/258; 257/E23.023

(57) ABSTRACT

Provided are methods of fabricating a circuit board and a semiconductor package, and a circuit board and a semiconductor package fabricated using the methods. The circuit board comprises: a lower wiring pattern disposed on an upper surface of a resin substrate comprising a filler; a resin layer disposed on the lower wiring pattern; an upper wiring pattern comprising a bonding pad disposed on the resin layer; and a passivation layer comprising an upper opening exposing the bonding pad. The resin substrate comprises a substrate opening exposing a lower surface of the lower wiring pattern.

### CROSS-REFERENCE TO RELATED PATENT APPLICATION

This application claims priority under 35 USC § 119 to Korean Patent Application No. 10-2007-0048291, filed on May 17, 2007 in the Korean Intellectual Property Office, the disclosure of which is incorporated herein in its entirety by reference.

### BACKGROUND

1. Technical Field

The present invention relates to methods of fabricating a circuit board and a semiconductor package, and a circuit board and a semiconductor package fabricated using the methods. More particularly, the present invention relates to methods of fabricating a circuit board and a semiconductor package, and a circuit board and a semiconductor package fabricated using the methods, which can improve the reliability of the semiconductor package.

2. Description of the Related Art

Semiconductor packages are manufactured using a method whereby a circuit board is populated with semiconductor chips, and a passivation layer is formed on the semiconductor chips so as to cover the semiconductor chips. However, thermal stress is generated due to a difference between the coefficients of thermal expansion (CTE) of the circuit board and the semiconductor chips. Such thermal stress deteriorates the reliability of the semiconductor packages. Consequently, a need remains for a method of manufacturing semiconductor packages that minimizes thermal stress.

### SUMMARY

The present invention provides methods of fabricating a circuit board and a semiconductor package, and a circuit board and a semiconductor package fabricated using the methods to reduce thermal stress between the circuit board and a semiconductor chip.

According to an aspect of the present invention, there is provided a circuit board including: a lower wiring pattern disposed on an upper surface of a resin substrate including a filler, wherein the resin substrate includes a substrate opening exposing a lower surface of the lower wiring pattern; a resin layer disposed on the lower wiring pattern; an upper wiring pattern including a bonding pad disposed on the resin layer; and a passivation layer including an upper opening exposing the bonding pad.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1H are cross-sectional views illustrating a method of manufacturing a circuit board, according to an embodiment of the present invention;

FIG. 2 is a cross-sectional view illustrating a method of fabricating a semiconductor package, according to an embodiment of the present invention;

FIG. 3 is a cross-sectional view illustrating a method of fabricating a semiconductor package, according to another embodiment of the present invention;

FIG. 4 is a cross-sectional view illustrating a method of fabricating a semiconductor package, according to another embodiment of the present invention;

FIG. 5 is a cross-sectional view illustrating a method of fabricating a semiconductor package, according to another embodiment of the present invention; and

FIG. 6 is a cross-sectional view illustrating a method of fabricating a semiconductor package, according to another embodiment of the present invention.

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thickness of layers and region are exaggerated for clarity. Like reference numerals in the drawings denote like elements, and thus their description will be omitted.

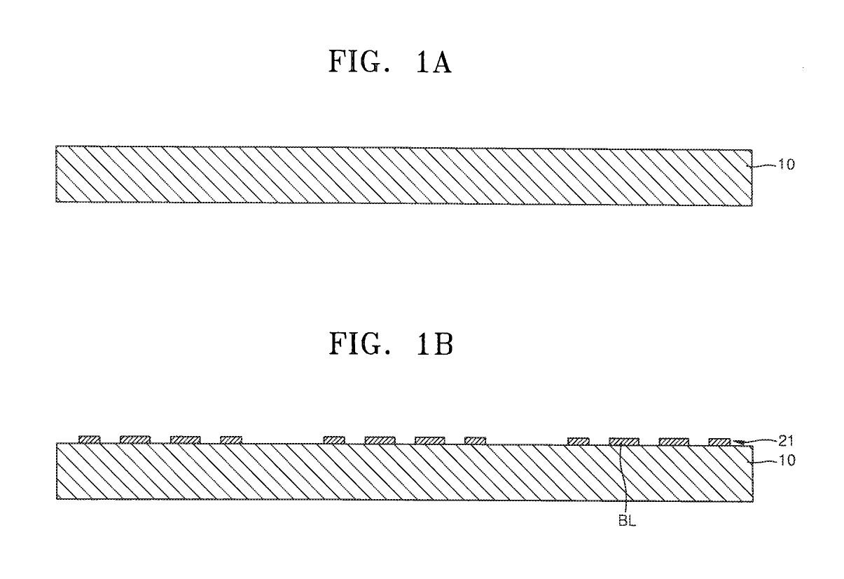

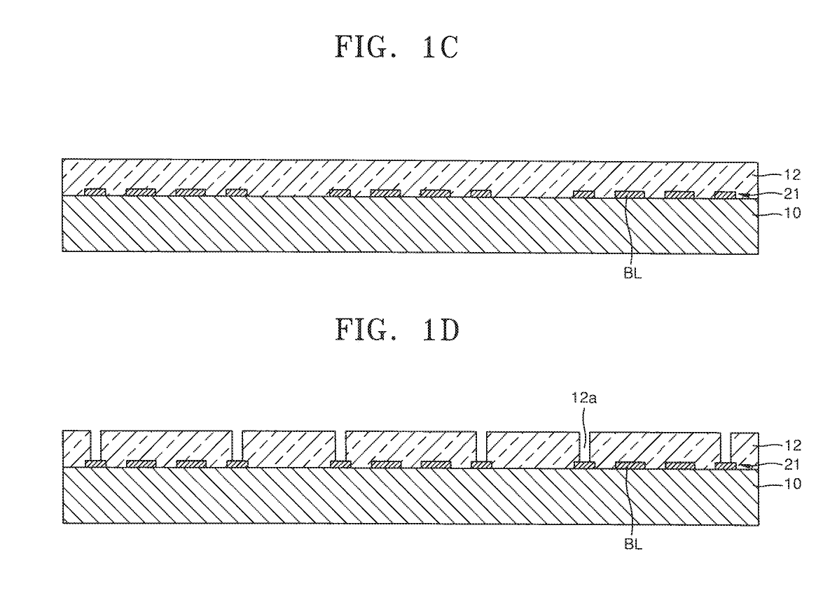

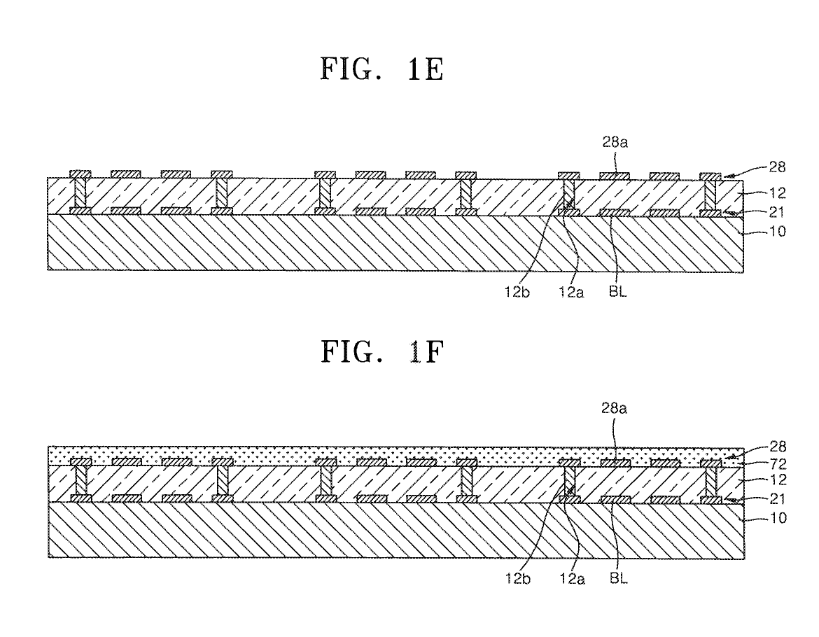

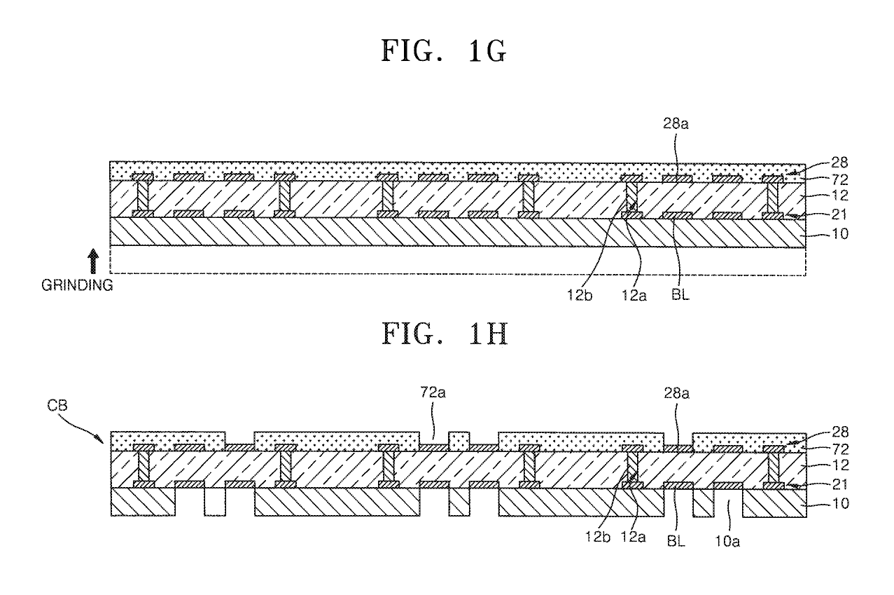

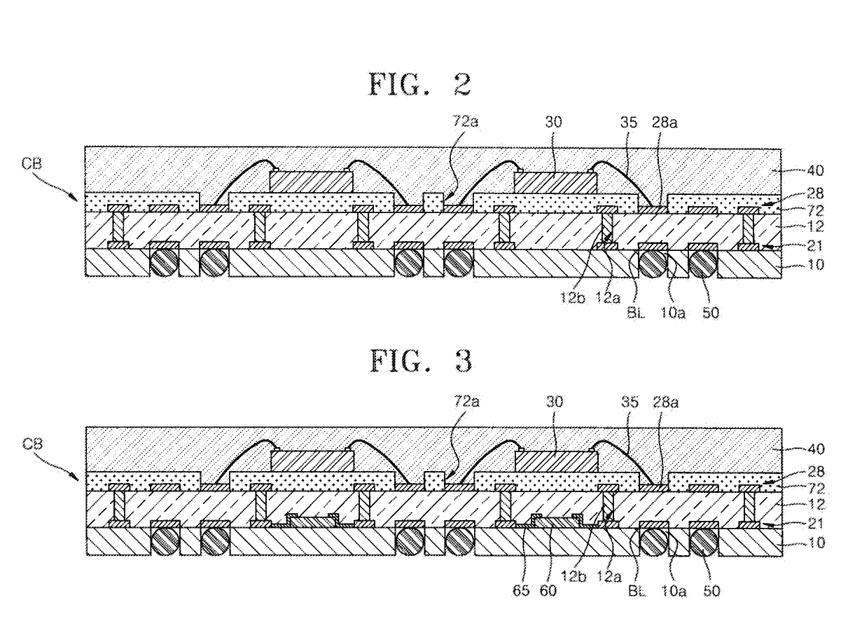

FIGS. 1A through 1H are cross-sectional views illustrating a method of manufacturing a circuit board, according to an embodiment of the present invention.

Referring to FIG. 1A, a resin substrate 10 includes a first filler. By adjusting the content and size of the first filler, the coefficient of thermal expansion (CTE) of the resin substrate 10 can be controlled. The first filler may include silica, graphite, aluminum or carbon black. The resin substrate 10 may be an epoxy resin substrate. The epoxy resin may be an ortho-cresol type epoxy resin, a novolac type epoxy resin or a bisphenol type epoxy resin.

The resin substrate 10 may be formed using a molding technique. In particular, the resin substrate 10 may be formed using a compression molding technique, a transfer molding technique, a flow free thin (FFT) molding technique or an injection molding technique. The resin substrate 10 may be formed to have a thickness in the range of about 50 to about 800 μm. When the thickness of the resin substrate 10 is less than about 300 μm, a supporting layer (not shown) may be attached to a lower surface of the resin substrate 10.

Referring to FIG. 1B, a lower wiring pattern 21 is formed on an upper surface of the resin substrate 10. The lower wiring pattern 21 may include a ball land BL. The lower wiring pattern 21 may be formed using an electrolyte plating technique, an electroless plating technique or an inkjet technique. The lower wiring pattern 21 may include copper, nickel, copper-nickel or gold.

Referring to FIG. 1C, a first resin layer 12 is formed on the lower wiring pattern 21. The first resin layer 12 may include a second filler. By adjusting the content, or amount, and size of the second filler, the CTE of the first resin layer 12 can be controlled. The second filler may include silica, graphite, aluminum or carbon black. The first resin layer 12 may be an epoxy resin layer. The epoxy resin may be an ortho-cresol type epoxy resin, a novolac type epoxy resin or a bisphenol type epoxy resin. The second filler can be different in one or more of size, amount, and material from the first filler. In other words, the second filler may comprise a different material than the first filler, the second filler may include a different amount of particles than the first filler, and the second filler may have particles of a different size than the first filler. In some applications, the first filler and the second filler may be formed using the same material.

The first resin layer 12 may be formed using a molding technique. In particular, the first resin layer 12 may be formed using a compression molding technique, a transfer molding technique, a FFT molding technique or an injection molding technique.

Referring to FIG. 1D, a first via hole 12a exposing a portion of the lower wiring pattern 21 is formed in the first resin layer 12. The first via hole 12a may be formed using a photolithography method or a laser drill method.

Referring to FIG. 1E, a conductive material is filled in the first via hole 12a to form a through electrode 12b in the first via hole 12a. The conductive material may include copper, nickel, copper-nickel or gold, and can be filled in the first via hole 12a using an electrolyte plating technique, an electroless plating technique or an inkjet technique.

Next, an upper wiring pattern 28 is formed on the first resin layer 12. The upper wiring pattern 28 includes a bonding pad 28a. Another portion of the upper wiring pattern 28 is electrically connected to the first wiring pattern 21 by the through electrode 12b. The upper wiring pattern 28 may be formed using an electrolyte plating technique, an electroless plating technique or an inkjet technique. The upper wiring pattern 28 may include copper, nickel, copper-nickel or gold.

Referring to FIG. 1F, an upper passivation layer 72 is formed on the upper wiring pattern 28. The upper passivation layer 72 may include an epoxy resin or a solder resist including a third filler. When the upper passivation layer 72 includes an epoxy resin, the upper passivation layer 72 can be formed using a molding technique. When the upper passivation layer 72 includes a solder resist, the upper passivation layer 72 can be formed using a laminating method. The third filler may be different in one or more of size, amount, and material from the first and second fillers.

Referring to FIG. 1G, when the thickness of the resin substrate 10 is about 500 μm or more, a lower surface of the resin substrate 10 is ground such that the thickness of the resin substrate 10 may be reduced to be about 300 μm or less. Alternatively, when a supporting layer (not shown) is formed on a lower surface of the resin substrate 10, the supporting layer is removed.

Referring to FIG. 1H, an upper opening 72a exposing the bonding pad 28a is formed in the upper passivation layer 72. A substrate opening 10a exposing a portion of the lower wiring pattern 21 (i.e., a lower surface of the ball land BL) is formed in the resin substrate 10. The upper opening 72a and the substrate opening 10a may each be formed independently using a photolithography method or a laser drill method.

Likewise, the resin substrate 10 is formed so as to include the first filler, and thus the CTE of the resin substrate 10 can be adjusted. Accordingly, the CTE of the circuit board CB including the resin substrate 10 can be adjusted so as to minimize thermal stress with respect to a semiconductor chip disposed on the circuit board CB. Therefore, the reliability of a semiconductor package including a circuit board fabricated using the method according to the current embodiment of the present invention can be improved. In addition, when the first resin layer 12 is formed so as to include the second filler, the expansion coefficient of the circuit board CB can be precisely adjusted.

In addition, since the resin substrate 10 is formed using a molding technique, the thickness of the resin substrate 10 can be easily adjusted, and thus the thickness of the circuit board CB including the resin substrate 10 can be easily adjusted. When the first resin layer 12 is formed using a molding technique, the thickness of the circuit board CB can be precisely adjusted.

FIG. 2 is a cross-sectional view illustrating a method of fabricating a semiconductor package, according to an embodiment of the present invention.

Referring to FIG. 2, an upper semiconductor chip 30 is disposed on the upper passivation layer 72 of the circuit board CB described with reference to FIG. 1H. The upper semiconductor chip 30 may be adhered to the upper passivation layer 72 by an adhesion layer (not shown). An electrode pad (not shown) of the upper semiconductor chip 30 is electrically connected to a bonding pad 28a exposed in the upper opening 72a of the upper passivation layer 72 using a conductive wire, or bonding wire, 35.

Next, a molding layer 40 is formed on the upper semiconductor chip 30 so as to cover the upper semiconductor chip 30. The molding layer 40 may be an epoxy molding layer including an epoxy mold compound. In addition, a conductive ball 50 is formed on the ball land BL exposed in the substrate opening 10a of the resin substrate 10.

FIG. 3 is a cross-sectional view illustrating a method of fabricating a semiconductor package, according to another embodiment of the present invention. The method of fabricating a semiconductor package according to the current embodiment of the present invention is similar to the method of FIG. 2 except for the following descriptions.

Referring to FIG. 3, prior to forming a first resin layer 12, a lower semiconductor chip 60 is disposed on an upper surface of a resin substrate 10. The lower semiconductor chip 60 may be adhered to the resin substrate 10 by an adhesion layer (not shown). An electrode pad (not shown) of the lower semiconductor chip 60 is electrically connected to a lower wiring pattern 21 using a connection wiring 65. The first resin layer 12 is formed so as to cover the lower semiconductor chip 60.

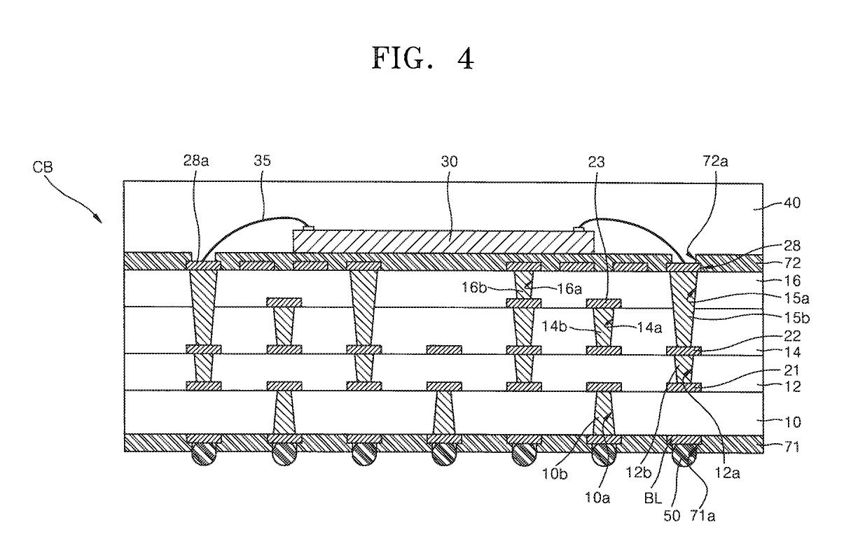

FIG. 4 is a cross-sectional view illustrating a method of fabricating a semiconductor package, according to another embodiment of the present invention. The method of fabricating a semiconductor package according to the current embodiment of the present invention is similar to the method of FIG. 2 except for the following descriptions.

Referring to FIG. 4, a lower wiring pattern 21 is formed on an upper surface of the resin substrate 10. A first resin layer 12 is formed on the lower wiring pattern 21. A first via hole 12a exposing a portion of a lower wiring pattern 21 is formed in the first resin layer 12. A conductive material is filled in the first via hole 12a, thus forming a first through electrode 12b in the first via hole 12a.

Next, a first intermediate wiring pattern 22 is formed on the first resin layer 12. A portion of the first intermediate wiring pattern 22 is electrically connected to the lower wiring pattern 21 by the through electrode 12b. A second resin layer 14 is formed on the first intermediate wiring pattern 22. The second resin layer 14 may also include a filler. By adjusting the content and size of the filler included in the second resin layer 14, the CTE of the second resin layer 14 can be controlled. The filler may be silica, graphite, aluminum or carbon black. The second resin layer 14 may be an epoxy resin layer. The epoxy resin may be an ortho-cresol type epoxy resin, a novolac type epoxy resin or a bisphenol type epoxy resin. The second resin layer 14 may also be formed using a molding technique. In particular, the second resin layer 14 may be formed using a compression molding technique, a transfer molding technique, a FFT molding technique or an injection molding technique.

A second via hole 14a exposing a portion of the first intermediate wiring pattern 22 is formed in the second resin layer 14. A conductive material is filled in the second via hole 14a to form a second through electrode 14b in the second via hole 14a. The conductive material may include copper, nickel, copper-nickel or gold, and can be filled in the second via hole 14a using an electrolyte plating technique, an electroless plating technique or an inkjet technique.

Next, a second intermediate wiring pattern 23 is formed on the second resin layer 14. A portion of the second intermediate wiring pattern 23 is electrically connected to the first intermediate wiring pattern 22 by the second through electrode 14b. A third resin layer 16 is formed on the second intermediate wiring pattern 23. The third resin layer 16 may also include a filler. By adjusting the content and size of the filler, the CTE of the third resin layer 16 can be controlled. The filler included in the third resin layer may be silica, graphite, aluminum or carbon black. The third resin layer 16 may be an epoxy resin layer. The epoxy resin may be an ortho-cresol type epoxy resin, a novolac type epoxy resin or a bisphenol type epoxy resin. The third resin layer 16 may also be formed using a molding technique. In particular, the third resin layer 16 may be formed using a compression molding technique, a transfer molding technique, a FFT molding technique or an injection molding technique.

A third via hole 16a exposing a portion of the second intermediate wiring pattern 23 is formed in the third resin layer 16. A fourth via hole 15a exposing a portion of the first intermediate wiring pattern 22 is formed in the third resin layer 16 and the second resin layer 14. At the same time as the formation of the third and the fourth via holes 15a and 16a, a substrate opening 10a exposing a portion of a lower surface of the lower wiring pattern 21 is formed in the resin substrate 10. A conductive material is filled in the third and fourth via holes 15a and 16a and the substrate opening 10a to form a third through electrode 16b, a fourth through electrode 15b and a connection electrode 10b, in the third and fourth via holes 15a and 16a and the substrate opening 10a, respectively. The conductive material may include copper, nickel, copper-nickel or gold. The third through electrode 16b, fourth through electrode 15b and connection electrode 10b are formed using an electrolyte plating technique, an electroless plating technique or an inkjet technique.

Next, an upper wiring pattern 28 is formed on the third resin layer 16. The upper wiring pattern 28 includes a bonding pad 28a. At the same time as the formation of the upper wiring pattern 28, a ball land BL may be formed on a lower surface of the resin substrate 10. The ball land BL may be connected to the connection electrode 10b so as to be electrically connected to the lower wiring pattern 21. An upper passivation layer 72 is formed on the upper wiring pattern 28, and a lower passivation layer 71 is formed on the ball land BL. The lower passivation layer 71 may be a solder resist layer. An upper opening 72a exposing the bonding pad 28a is formed in the upper passivation layer 72. A lower opening 71a exposing the ball land BL is formed in the lower passivation layer 71.

An upper semiconductor chip 30 is disposed on the upper passivation layer 72. The upper semiconductor chip 30 may be adhered to the upper passivation layer 72 by an adhesion layer (not shown). An electrode pad (not shown) of the upper semiconductor chip 30 is electrically connected to a bonding pad 28a exposed in the upper opening 72a using a conductive wire 35.

Next, a molding layer, or encapsulant, 40 is formed on the semiconductor chip 30 so as to cover the semiconductor chip 30. In addition, a conductive ball 50 is formed on the ball land BL exposed in the lower opening 71a.

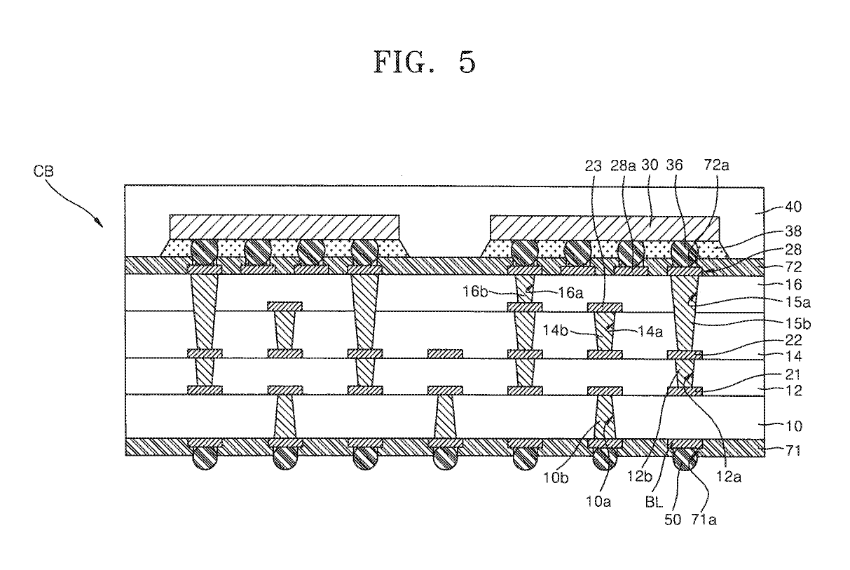

FIG. 5 is a cross-sectional view illustrating a method of fabricating a semiconductor package, according to another embodiment of the present invention. The method of fabricating a semiconductor package according to the current embodiment of the present invention is similar to the method of FIG. 4 except for the following descriptions.

Referring to FIG. 5, an upper semiconductor chip 30 is disposed on an upper passivation layer 72. The upper semiconductor chip 30 includes an electrode pad (not shown) and a conductive bump 36 formed on the electrode pad. The conductive bump 36 contacts a bonding pad 28a exposed in an upper opening 72a of the upper passivation layer 72 so as to be electrically connected to the bonding pad 28a.

An underfill layer 38 is formed between the upper semiconductor chip 30 and the upper passivation layer 72. Next, a molding layer 40 is formed on the upper semiconductor chip 30 so as to cover the upper semiconductor chip 30.

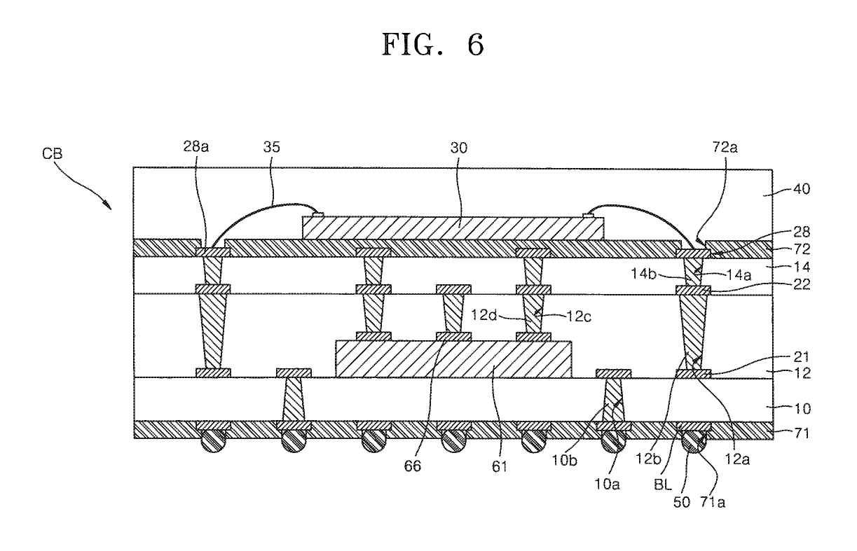

FIG. 6 is a cross-sectional view illustrating a method of fabricating a semiconductor package, according to another embodiment of the present invention. The method of fabricating a semiconductor package according to the current embodiment of the present invention is similar to the method of FIG. 2 except for the following descriptions.

Referring to FIG. 6, a lower wiring pattern 21 is formed on an upper surface of a resin substrate 10. In addition, a lower semiconductor chip 61 is disposed on the upper surface of the resin substrate 10. An electrode pad 66 is formed on an upper surface of the lower semiconductor chip 61. A first resin layer 12 is formed on the lower wiring pattern 21 and the lower semiconductor chip 61. A first via hole 12a exposing a portion of the lower wiring pattern 21 and a second via hole 12c exposing the electrode pad 66 are formed in the first resin layer 12. A conductive material is filled in the first and second via holes 12a and 12c to form a first through electrode 12b and a second through electrode 12d filling the first and second via holes 12a and 12c, respectively.

Next, a first intermediate wiring pattern 22 is formed on the first resin layer 12. A portion of the first intermediate wiring pattern 22 is electrically connected to the lower wiring pattern 21 by the first through electrode 12b. Another portion of the first intermediate wiring pattern 22 is electrically connected to the electrode pad 66 by the second through electrode 12d.

A second resin layer 14 is formed on the first intermediate wiring pattern 22. The second resin layer 14 may also include a filler. By adjusting the content and size of the filler, the CTE of the second resin layer 14 can be controlled. The filler may include silica, graphite, aluminum or carbon black. The second resin layer 14 may be an epoxy resin layer. The epoxy resin may be an ortho-cresol type epoxy resin, a novolac type epoxy resin or a bisphenol type epoxy resin. The second resin layer 14 may also be formed using a molding technique. In particular, the second resin layer 14 may be formed using a compression molding technique, a transfer molding technique, a FFT molding technique or an injection molding technique.

A third via hole 14a exposing a portion of the first intermediate wiring pattern 22 is formed in the second resin layer 14. At the same time as the formation of the third via hole 14a, a substrate opening 10a exposing a portion of a lower surface of the lower wiring pattern 21 may be formed in the resin substrate 10. A conductive material is filled in the third via hole 14a and the substrate opening 10a to form a third through electrode 14b and a connection electrode 10b in the third via hole 14a and the substrate opening 10a, respectively. The conductive material may include copper, nickel, copper-nickel or gold, and may be filled in the third via hole 14a and the substrate opening 10a using an electrolyte plating technique, an electroless plating technique or an inkjet technique.

Next, an upper wiring pattern 28 is formed on the second resin layer 14. The upper wiring pattern 28 includes a bonding pad 28a. At the same time as the formation of the upper wiring pattern 28, a ball land BL is formed on a lower surface of the resin substrate 10. An upper passivation layer 72 is formed on the upper wiring pattern 28. A lower passivation layer 71 is formed on the ball land BL. An upper opening 72a exposing the bonding pad 28a is formed in the upper passivation layer 72. A lower opening 71a exposing the ball land BL is formed in the lower passivation layer 71.

An upper semiconductor chip 30 is disposed on the upper passivation layer 72. The upper semiconductor chip 30 may be adhered to the upper passivation layer 72 by an adhesion layer (not shown). An electrode pad (not shown) of the upper semiconductor chip 30 is electrically connected to the bonding pad 28a exposed in the upper opening 72a using a conductive wire 35.

Next, a molding layer 40 is formed on the semiconductor chip 30 so as to cover the semiconductor chip 30. In addition, a conductive ball 50 is formed on the ball land BL exposed in the lower opening 71a.

As described above, according to some embodiments of the present invention, a resin layer includes a filler, and thus the CTE of the resin layer can be controlled and the CTE of a circuit board including the resin layer can be reduced so as to substantially reduce thermal stress with respect to a semiconductor chip disposed on the circuit board. Accordingly, the reliability of a semiconductor package can be significantly improved.

In addition, since the resin layer may be formed using a molding technique, the thickness of the resin layer can be easily adjusted, and thus the thickness of the circuit board including the resin layer can be easily adjusted.

According to an aspect of the present invention, there is provided a method of fabricating a circuit board, including: forming a lower wiring pattern on an upper surface of a resin substrate including a filler; forming a first resin layer on the lower wiring pattern; forming an upper wiring pattern including a bonding pad on the first resin layer; forming a passivation layer including an opening exposing the bonding pad; and forming a substrate opening exposing a portion of the lower wiring pattern in the resin substrate.

According to another aspect of the present invention, there is provided a method of fabricating a semiconductor package, including: forming a lower wiring pattern on an upper surface of a resin substrate including a filler; forming a resin layer on the lower wiring pattern; forming an upper wiring pattern including a bonding pad on the resin layer; forming a passivation layer including an upper opening exposing the bonding pad on the upper wiring pattern; forming a substrate opening exposing a portion of the lower wiring pattern, in the resin substrate; and disposing an upper semiconductor chip, which is electrically connected to the bonding pad, on the passivation layer.

According to another aspect of the present invention, there is provided a circuit board including: a lower wiring pattern disposed on an upper surface of a resin substrate including a filler, wherein the resin substrate includes a substrate opening exposing a lower surface of the lower wiring pattern; a resin layer disposed on the lower wiring pattern; an upper wiring pattern including a bonding pad disposed on the resin layer; and a passivation layer including an upper opening exposing the bonding pad.

According to another aspect of the present invention, there is provided a semiconductor package including: a lower wiring pattern disposed on an upper surface of a resin substrate including a filler, wherein the resin substrate includes a substrate opening exposing a lower surface of the lower wiring pattern; a resin layer disposed on the lower wiring pattern; an upper wiring pattern including a bonding pad disposed on the resin layer; a passivation layer including an upper opening exposing the bonding pad; and an upper semiconductor chip, which is electrically connected to the bonding pad, disposed on the passivation layer.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A circuit board comprising:
a resin substrate comprising a first filler;
a lower wiring pattern disposed on the resin substrate,
wherein the resin substrate includes a substrate opening exposing a lower surface of the lower wiring pattern;
a resin layer disposed on an upper surface of the lower wiring pattern;
an upper wiring pattern overlying the resin layer, the upper wiring pattern including a bonding pad; and
a passivation layer overlying the upper wiring pattern, the passivation layer including an upper opening exposing the bonding pad.

2. The circuit board of claim 1, wherein the resin layer comprises a second filler.

3. The circuit board of claim 1, wherein the resin substrate comprises an epoxy resin and the resin layer comprises an epoxy resin.

4. The circuit board of claim 1, further comprising:
a through electrode in the resin layer, the through electrode electrically connecting the lower wiring pattern to the upper wiring pattern.

5. A semiconductor package comprising:
a resin substrate including a first filler;
a lower wiring pattern disposed on the resin substrate, wherein the resin substrate comprises a substrate opening exposing a lower surface of the lower wiring pattern;
a resin layer disposed on an upper surface of the lower wiring pattern;
an upper wiring pattern overlying the resin layer, the upper wiring pattern including a bonding pad;
a passivation layer defining an upper opening exposing the bonding pad; and
an upper semiconductor chip disposed on the passivation layer and electrically connected to the bonding pad.

6. The semiconductor package of claim 5, further comprising:
a though electrode in the resin layer, the through electrode electrically connecting the lower wiring pattern to the upper wiring pattern.

7. The semiconductor package of claim 5, further comprising:
a lower semiconductor chip disposed between the resin layer and the resin substrate and electrically connected to the lower wiring pattern.

8. The semiconductor package of claim 5, further comprising one or more intermediate resin layers disposed between the resin layer and the resin substrate.

9. The semiconductor package of claim 8, further comprising one or more intermediate wiring patterns disposed on the additional resin layers.

10. The semiconductor package of claim 9, further comprising a plurality of through electrodes electrically connecting the upper wiring pattern, the lower wiring pattern, and the intermediate wiring patterns.

11. The semiconductor package of claim 8, further comprising a lower passivation layer disposed on a lower surface of the resin substrate.

12. The semiconductor package of claim 11, further comprising a plurality of ball lands disposed on the lower surface of the resin substrate and a plurality of conductive balls disposed on the ball lands.

13. The semiconductor package of claim 12, further comprising a through electrode disposed in the substrate opening and electrically connecting the lower wiring pattern to at least one of the ball lands.

14. The semiconductor package of claim 8, further comprising:
a lower semiconductor chip disposed on the resin substrate; and
at least one through electrode electrically connecting the lower semiconductor chip to the upper wiring pattern.

15. The semiconductor package of claim 5, wherein the resin layer comprises a second filler.

16. The semiconductor package of claim 5, wherein the first filler is different from the second filler in one or more of size, amount, and material.
